(19) United States
(12) Patent Application Publication
(10) Pub. No.: US 2026/0050112 A1
(43) Pub. Date: Feb. 19, 2026

(54) BLAZED GRATING BASED REFLECTIVE SPECTRAL PURITY FILTER FOR EUV IMAGING SYSTEMS

(71) Applicant: KLA Corporation, Milpitas, CA (US)

(72) Inventors: Wenhua Zhu, Albany, CA (US); Rui-Fang Shi, Cupertino, CA (US); Rajeev Rajendran, San Francisco, CA (US)

(21) Appl. No.: 19/283,884

(22) Filed: Jul. 29, 2025

Related U.S. Application Data
(60) Provisional application No. 63/682,799, filed on Aug. 14, 2024.

(51) Int. Cl. G02B 5/18; G02B 5/20; G02B 5/26; G03F 1/22; G03F 7/00

(52) U.S. Cl. CPC G02B 5/1861; G02B 5/1838; G02B 5/208; G02B 5/26; G03F 1/22; G03F 7/70033; G03F 7/70191; G03F 7/702; G03F 7/70233; G03F 7/7065; G03F 7/706837; G03F 7/706849

(57) ABSTRACT

A reflective spectral purity filter (SPF) for extreme ultraviolet (EUV) light includes a substrate having a reflective surface and an angle of incidence of at least 60 degrees, and a blazed diffraction grating formed on the substrate, the blazed diffraction grating having a grating pitch and blaze angle (fixed or variable) configured to simultaneously diffract incident EUV light into a higher-order diffraction angle and confine out-of-band (OOB) light to a 0th order reflection angle to angularly separate the EUV light and the OOB light. An imaging system including the reflective SPF, the imaging system having a field of view (FOV) configured to collect the spatially filtered EUV light and reject the OOB light based on angular separation of the lights.

### CROSS REFERENCE TO RELATED APPLICATION

The present application claims the benefit under 35 U.S.C. § 119 (e) of U.S. Provisional Application Ser. No. 63/682,799, filed Aug. 14, 2024, which is incorporated herein by reference in its entirety.

### TECHNICAL FIELD

The present disclosure generally relates to imaging systems, and in particular, to reflection-based extreme ultraviolet (EUV) spectral purity filters (SPFs) for use in imaging systems.

### BACKGROUND

Extreme ultraviolet (EUV) spectral purity filters (SPFs) are specialized optical components designed to selectively transmit EUV light (typically around 13.5 nm) while blocking out-of-band (OOB) wavelengths such as visible light, infrared (IR) light, or soft x-rays. Uses of such filters include, but are not limited to, EUV lithography, metrology, detector protection, and photomask inspection.

Traditional EUV SPFs operate on the principles of absorption and reflection. Absorption-based filters use thin films of materials (e.g., zirconium, boron, aluminum) which transmit EUV light while absorbing unwanted longer wavelengths such as visible and IR light. Reflection-based filters rely on Bragg reflection from precisely engineered multilayer stacks (e.g., Mo/Si, Mo/B₄C) to reflect a narrow band of EUV light while reflecting or absorbing OOB wavelengths. Regardless of type, traditional SPFs are incapable of near 100% EUV transmission, with absorption-based SPFs limited to no more than about 50% transmission and reflective-based SPFs limited to no more than about 70% transmission. Other disadvantages of traditional EUV SPFs include, but are not limited to, thermal degradation, limited spectral tunability, sensitivity to grating surface quality, EUV light attenuation, and handling durability and reliability.

Therefore, what is needed is an EUV SPF filter solution with improved performance in terms of efficiency, rejection, tunability, attenuation, etc.

### SUMMARY

A reflective spectral purity filter (SPF) for EUV light is disclosed, in accordance with one or more embodiments of the present disclosure. In an illustrative embodiment, the reflective SPF includes a substrate (e.g., grazing incidence mirror) including a reflective surface having an angle of incidence of at least 60 degrees, and a blazed diffraction grating formed on the substrate, the blazed diffraction grating having a predetermined grating pitch and blaze angle configured to simultaneously diffract incident EUV light into a higher-order diffraction angle and confine out-of-band (OOB) light to a 0th order reflection angle to angularly separate the EUV light and the OOB light.

An imaging system is disclosed, in accordance with embodiments of the present disclosure. In an illustrative embodiment, the imaging system includes an extreme ultraviolet (EUV) light source configured to generate a beam of EUV light containing non-negligible out-of-band (OOB) light, a reflective spectral purity filter (SPF) for EUV light, a stage configured to hold a substrate to be inspected, an imaging system including collection optics having a field of view (FOV), one or more detectors configured to detect EUV light reflected from the substrate, and a system controller including one or more processors. In embodiments, the reflective SPF includes a substrate having a reflective surface with an angle of incidence of at least 60 degrees, and a blazed diffraction grating formed on the substrate, the blazed diffraction grating having a predetermined grating pitch and a predetermined blaze angle configured to simultaneously diffract incident EUV light into a higher-order diffraction angle and confine the non-negligible OOB light to a 0th order reflection angle to angularly separate the EUV light and the non-negligible OOB light.

A method for imaging a substrate is disclosed, in accordance with embodiments of the present disclosure. In an illustrative embodiment, the method includes generating a beam of EUV light containing non-negligible out-of-band (OOB) light, spatially filtering the EUV light from the OOB light using a reflective SPF according to the present disclosure, directing the spatially filtered EUV light toward a substrate held on a stage, collecting the spatially filtered EUV light reflected from the substrate in a field of view (FOV) of an imaging system, and detecting the collected spatially filtered EUV light to determine at least one a pattern and a defect of the substrate.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention, and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates a reflective SPF for EUV light, in accordance with one or more embodiments of the present disclosure.

FIG. 2 illustrates a reflective SPF implemented in an imaging system, in accordance with one or more embodiments of the present disclosure.

FIGS. 3A and 3B illustrate alternative blazed diffraction gratings, in accordance with one or more embodiments of the present disclosure.

FIG. 4 illustrates a process flow diagram of the operational steps of the highly simplified APMI system illustrated in FIG. 2, in accordance with one or more embodiments of the present disclosure.

FIG. 5 illustrates grating diffraction efficiency in a working example, in accordance with one or more embodiments of the present disclosure.

FIGS. 6A and 6B illustrate relative spectral transmission of the reflective SPF and a typical EUV multilayer filter and their combination, respectively, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

An extreme ultraviolet (EUV) reflective spectral purity filter (SPF) (herein “SPF” or “reflective SPF”) is disclosed, including a blazed diffraction grating formed by etching and/or coating on a grazing incidence mirror surface. In embodiments, the filter operates in reflection mode and is configured to achieve near-complete transmission of EUV wavelengths (limited only by the intrinsic reflectance of the mirror coating), while substantially rejecting out-of-band (OOB) light above about 100 nm. As a standalone optical component, the disclosed SPF can deliver residual OOB levels approaching zero percent.

When implemented in conjunction with conventional multilayer-coated mirrors within an EUV imaging system, the filter provides enhanced spectral discrimination by effectively eliminating non-EUV wavelengths outside the operational in-band range (approximately 13-14 nm). This dual-stage filtering mechanism enables significantly improved spectral purity over traditional transmissive SPFs, which are typically limited to no more than about 70% EUV transmission and allow a non-negligible fraction of residual OOB light. Furthermore, transmissive filters are known to exhibit limited operational lifespans due to light-induced degradation arising from photon absorption.

The reflective SPF according to present disclosure circumvents these issues by relying on diffraction and dispersion phenomena rather than absorption for OOB suppression. This design inherently reduces susceptibility to light damage, thereby increasing the operational lifetime of the filter. Additionally, the reflective nature of the reflective SPF allows higher EUV photon flux to reach the imaging plane, resulting in improved system throughput and increased uptime in applications such as actinic patterned mask inspection (APMI) and lithography.

While the primary context of the present disclosure is EUV spectral purity filtering, the underlying principles are broadly applicable across other spectral regions, for instance soft X-ray, deep ultraviolet (DUV), and vacuum ultraviolet (VUV). The SPF may thus be employed in a variety of inspection, metrology, or lithographic systems where suppression of unwanted out-of-band light is necessary to preserve image fidelity or measurement accuracy.

The disclosed reflective SPF offers significant improvements over existing transmission-based SPF solutions including, but not limited to: enhanced spectral performance (e.g., the SPF achieves near-complete rejection of OOB light while maintaining nearly 100% transmission of EUV wavelengths, thereby maximizing system signal-to-noise ratio (SNR)); improved durability (e.g., by operating in a reflective geometry rather than relying on photon absorption, the SPF reduces light-induced damage to the filter structure thereby extending operational life and reliability); protection of downstream optical components (e.g., effective OOB rejection minimizes photon contamination to subsequent/downstream optical components thereby preserving system performance); reduced transmission loss (e.g., the reflective configuration allows for fewer and less complex coating layers, particularly over the grating step surfaces, thereby minimizing transmission loss due to coating imperfections); simplified fabrication (e.g., the use of a fixed grating pitch and blazed angle, enabled by the relatively small angular variations in reflective geometries, reduces fabrication complexity compared to traditional multilayer or transmission-based filters); and cost reduction (e.g., eliminate the need for additional upstream/downstream gratings or mirrors, leading to reduced system cost, increased photon throughput, and improved overall efficiency).

The reflective SPF according to the present disclosure is based on the concept of blazed grating-based angular discrimination between EUV and OOB wavelengths. According to this first concept, a varied scattering response of light in the EUV and OOB spectral domains can be obtained from a blazed diffraction grating. In embodiments, a blazed diffraction grating according to the present disclosure, defined by a pitch T and a blaze angle θ_{B} is configured to deflect and confine EUV light to designated angles. By tuning the blaze angle and the pitch, as described in detail below, the EUV light can be deflected away from the 0th order and exclusively confined to be within specific higher diffraction orders (herein “blazed orders”), for example, the +1st order. This results in near-complete suppression of the 0th order for the EUV wavelengths.

While the EUV light scatters to the higher order(s) in its entirety from a blazed structure, the OOB scattering differs from that of EUV, at the grating pitch T and blaze angle θ_{B} designed to optimize deflection for the EUV light. First, a small blaze angle sufficient to deflect the EUV light into the blazed order, forms a very weak phase object for OOB light. This leads to most of the OOB light being confined to the 0th order. Further, even in the event of scattering outside the 0th order, the 1st diffraction order of OOB is far spaced in angle compared to the +1st diffraction of EUV light, leading to a clear angular separation and isolation of the +1st order EUV light from both the 0th order and +1st order (and higher orders) of OOB. Blazed structures according to the present disclosure are therefore optimally designed to isolate the EUV light from the OOB light.

By combining the EUV and OOB light scattering properties from the grazing angle blazed mirror, the reflective SPF can be designed where the EUV scattered light is confined to the blaze order while the OOB light is either confined in the 0th order or deflected to higher orders. In either case, the reflective SPF according to the present disclosure operates to angularly isolate the EUV path from the OOB light path(s) based on pitch and blaze angle. This is possible due to the near complete transfer of EUV light from the 0th order to the +1st order by the blaze even at small blaze angles, the weak phase provided by the small blaze angles leading to very low OOB diffraction and hence substantial energy content in the 0th order, and the large order separation at OOB wavelengths keeping any remnant scattering far away from the EUV deflected light.

The reflective SPF according to the present disclosure is further based on the concept of etching the blazed grating on a grazing incidence mirror (as opposed to a normal incidence mirror). The present inventors have found that grazing incidence optical elements offer intrinsic EUV reflectivity without the otherwise necessary multilayered coatings prevalent at normal incidence. Further, unlike reflection from a multilayered coating, the EUV reflectivity has a higher reflectance amplitude at grazing incidence. Hence, in addition to the use of blazed structures the reflective SPF according to the present disclosure is a based on a grazing incident reflection geometry which intrinsically has high reflectance for EUV, with an angle of incidence θᵢ of the light of at least 60 degrees.

Unlike normal incidence mirrors coated with multilayers, a grazing incidence mirror according to the present disclosure has several advantages, such as the ability to achieve high intrinsic EUV reflectance with typically one or a few layers of coatings, significantly less scatter loss from surface roughness compared to normal incident reflection, fewer layers translate to minimal transmission loss due to the imperfections/coating artifacts over the grating step area, and the angle of incidence variation (Δθᵢ) on a grazing incidence mirror is much smaller than a normal incidence mirror. This allows the use of a fixed blazing angle and grating pitch over the entire mirror without losing significant transmission due to intrinsic angle of incidence dependance, thereby reducing the complexity of fabrication.

In embodiments using a curved substrate, aberration compensation of the etched blazed grating may be mitigated by etching a blazed grating having a variable grating pitch T and blaze angle θ_{B} across the surface of the substrate. In embodiments, optical aberrations may be due to the curvature of the substrate, blaze angle of the grating, off-axis angles, etc., and compensation may include optimizing the blazed grating pattern (e.g., variable groove spacing across the surface), local adjustments of the pitch and blaze angle, etc. In embodiments, grating pitch T may range from about 100 nm to about 10 μm but extendable to about 25 nm to about 100 μm, while blaze angle θ_{B} may range from about 0.1 degree to about 5.0 degrees but extendable to about 0.01 degrees to about 30.0 degrees.

In embodiments, the blazed grating may be implemented on a flat substrate with mirror curvature encoded by varying the grating pitch. In other words, the flat substrate can be etched with a varied grating pitch to emulate a curved substrate, thus allowing implementation on either flat or curved substrates with aberration compensation capability to correct system aberrations. For example, a variable blazed grating can be etched on a flat mirror to emulate the optical focusing properties of a curved mirror by modulating the groove spacing and blaze angle across the surface.

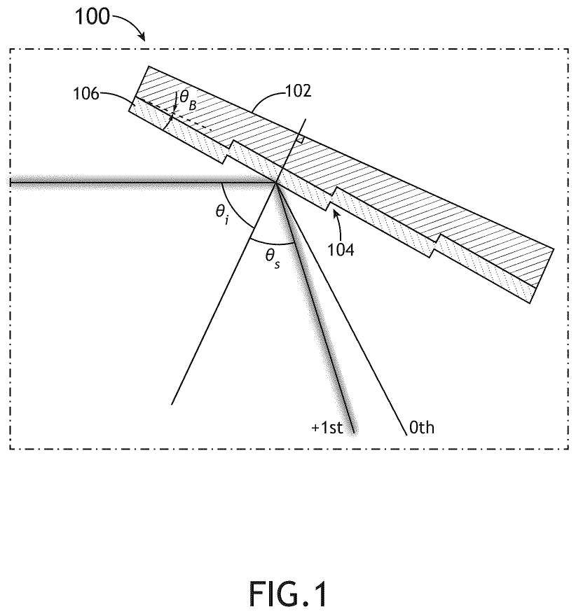

FIG. 1 schematically illustrates a reflective SPF 100 configured for operation in the EUV spectral range. In embodiments, the reflective SPF includes a grazing incidence mirror 102 (substrate), configured to angles of incidence of at least 60 degrees, on which is formed a blazed diffraction grating 104. In embodiments, the blazed diffraction grating 104 has a predetermined grating pitch T and blaze angle θ_{B} selected to optimize diffraction behavior for the EUV wavelength range. In some embodiments, the reflective SPF 100 may be formed by etching the blazed diffraction grating 104 on the grazing incidence mirror 102 followed by depositing one or more coating layers 106 to maximize EUV reflectance.

The blazed diffraction grating 104 is configured such that incident EUV light is diffracted into a higher-order diffraction angle, for instance the +1st order. Simultaneously, OOB light (e.g., wavelengths above 100 nm) are primarily reflected into the 0th order and/or diffracted into higher orders that are angularly separated from the EUV diffraction path. This differential scattering behavior creates angular isolation/separation between the EUV and OOB light components such that, when implemented in an imaging system, the imaging field of view (FOV) can be used as a spatial filter to reject the OOB light from the EUV light at the reticle plane.

In embodiments, the blazed diffraction grating 104 is constant along the grazing incidence mirror 102 and has a predetermined grating pitch T and blaze angle θ_{B} to ensure consistent optical performance and reduce fabrication complexity. In embodiments, the angular separation between the different light paths corresponding to the different orders may range from about 0.01 degrees to about 30.0 degrees to facilitate angular filtering and redirection of OOB wavelengths. In embodiments, the blazed diffraction grating 104 may be variable across the surface of a curved or flat substrate (e.g., mirror).

In embodiments, the blazed diffraction grating 104 is tuned to achieve an EUV transmission efficiency of at least 80%, more preferably at least 90%, and even more preferably at least 99%, with OOB suppression of at least 99%. In embodiments, the coating layer 106 may be a single layer or multilayer coating selected to maximize EUV reflectivity while minimizing scattering loss due to surface roughness. Suitable substrate materials may be selected depending on the optical requirements of the system in which the reflective SPF 100 is integrated. In embodiments, the reflective SPF 100 may be implemented as a standalone filter or used in conjunction with other multilayer optics in systems such as EUV lithography, wafer inspection, and actinic metrology systems.

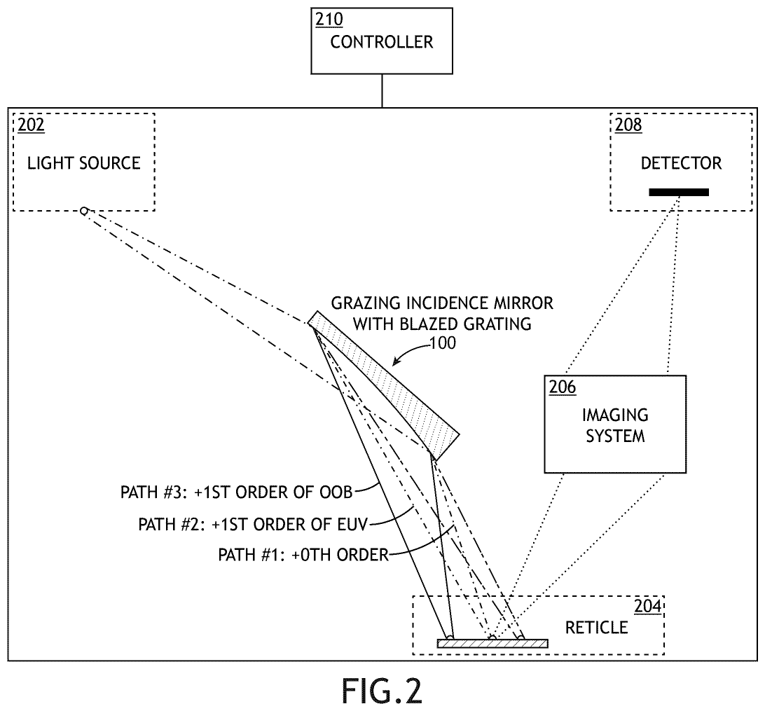

FIG. 2 illustrates the reflective SPF 100 implemented in an inspection system such as the highly simplistic actinic patterned mask inspection (APMI) system 200 shown utilizing EUV lithography to detect defects on patterned photomasks at the actinic wavelength (e.g., 13.5 nm). In embodiments, the APMI system 200 includes an EUV light source 202 such as a laser-produced plasma source or synchrotron configured to generate light at a wavelength of 13.5 nm. The APMI system 200 further includes illumination optics including the reflective SPF 100 configured to perform as discussed above to simultaneously separate EUV light and non-negligible OOB light originated from the EUV light source 202. The APMI system 200 further includes a reticle (mask) stage 204 configured to hold and scan the patterned EUV mask or other substrate under inspection. The APMI system 200 further includes an imaging system 206 including imaging such as multilayer-coated EUV mirrors or other optics for forming images of the reticle patterns or defects. The APMI system 200 further includes a detector 208, for instance an EUV-sensitive CCD, CMOS, or the like configured to capture images for the defect detection. In embodiments, the detector 208 may be part of a system including a plurality of detectors. Finally, the APMI system 200 includes a controller 210.

In embodiments, the controller 210 includes one or more processors configured to execute program instructions maintained in a memory. In this regard, the one or more processors may execute any of the various process steps described throughout the present disclosure. In embodiments, the controller 210 includes hardware and software elements. The controller 210 may be communicatively coupled with any component of the APMI system 200 or any additional components outside of the APMI system 200. In embodiments, the controller 210 may be configured to receive data from a component such as, but not limited to, the detector 208. For example, the controller 210 may receive any combination of raw data, processed data (e.g., inspection results), and/or partially processed data. In another embodiment, the controller 210 may perform processing steps based on the received data. For example, the controller 210 as it pertains to a lithography mask may perform defect inspection steps including defect identification, classification, and sorting. In embodiments, the controller 210 may control and/or direct (e.g., via control signals) any component of the APMI system 200. For example, any combination of elements associated with the illumination pathway and/or the collection pathway may be adjustable. In this regard, the controller 210 may modify any combination of illumination conditions or imaging conditions.

In use of the APMI system 200, the EUV light source 202 with non-negligible OOB content is conjugated onto the reticle plane through the reflective SPF 100 to illuminate the reticle imaging field of view (FOV). The blazed diffraction grating 106 etched on the grazing incidence mirror 102 separates the diffraction orders in angle space. To illustrate the concept of spectral filtering the light dispersion from the reflective SPF 100 is shown dispersed along three separate light paths. Path #1 corresponds to the 0th order beams for both EUV light and OOB light. Path #2 corresponds to the +1st order for the EUV light which by virtue of a matched design (see equations below) is also the blazed diffraction order for EUV. Path #3 corresponds to the +1st order of OOB light at a specific wavelength (in principle this path can be an angular band when a broad OOB spectrum is considered). The +1st order of EUV light is the desired beam that the imaging system is seeing. This is achieved by ensuring that the FOV of the imaging system captures only the conjugate as defined by the EUV deflected beam. The imaged conjugates of the object through the other beamlets are deliberately designed to be outside the imaging FOV.

In embodiments, the optimal blaze angle for confining the EUV light into the first order is derived as described below. The incident angle θᵢ, the 1st order diffraction angle θₛ, and the blaze angle θ_{B} are related as:

$${θ}_{B} = ( {θ}_{i} - {θ}_{s} ) / 2 \qquad ( 1 )$$

Further, from Bragg diffraction condition, the +1st order diffraction angle is calculated as

$$sin {θ}_{s} = sin {θ}_{i} - \frac{λ}{T} \qquad ( 2 )$$

where λ is wavelength, and T is grating pitch. The optimal blaze angle that meets both of these criteria which allows light defection into 1st order is given by

$${θ}_{B} = ( {θ}_{i} - asin \{ sin {θ}_{i} - \frac{λ}{T} \} ) / 2 \qquad ( 3 )$$

In embodiments, considering the wavelength of EUV light is very short, the EUV light requires a small angle (e.g., about 0.5 degrees) to get deflected into the +1st order due to the blazed diffraction grating 106. Such a small angle cannot create enough phase shift for the other longer wavelengths of OOB light, thus most of energy from other longer wavelengths is diffracted to the 0th order corresponding to Path #1. Even if there are some residual energies going to the 1st order, it will have much larger scattered angle according to Eq. (2) (due to the large order spacing). FIG. 2 also shows the deflection of the +1st order from OOB light, which is further separated from the +1st order of EUV. For shorter wavelengths in the OOB spectrum close to the EUV wavelengths, there could in principle be an overlap with the +1st order EUV beam due to the finite beam size. However, for these wavelength bands the upstream EUV multilayer coatings in the illumination system have very low reflectance and are filtered earlier. Also, shorter wavelengths have lower spatial coherence lengths degrading the diffraction efficiency.

In summary, the EUV light is confined to its +1st order and the OOB light is either predominantly in the 0th order or in higher orders but far (angularly spaced) from the EUV light or if they have an overlap with EUV light (wavelengths close to EUV for instance), attenuated by the material properties of normal incidence EUV mirrors upstream in the EUV illumination system or downstream in the EUV imaging system. As such, the concept of the reflective SPF 100 exploits the well-defined angular separation offered by the blazed grating mirror between EUV and OOB translating to the lateral shifts and isolation in the reticle plane. Based on this, it is possible to isolate the EUV +1st order by spatially filtering the same in the reticle plane either by physically slits in the illumination or more elegantly using the imaging FOV as a natural spatial filter as described in FIG. 2. In fact, this separation and FOV filtering removes most of other OOB scattering orders from reaching the detector allowing near 100% OOB rejection at the plane of interest, which is the detector plane, for wavelengths above 100 nm without considering a multilayer mirror. Further, in case of multilayer mirror usage, which is common in EUV imaging systems, it provides an almost perfect narrow EUV band system level filtering of near 100% OOB beyond EUV in-band (e.g., 13-14 nm).

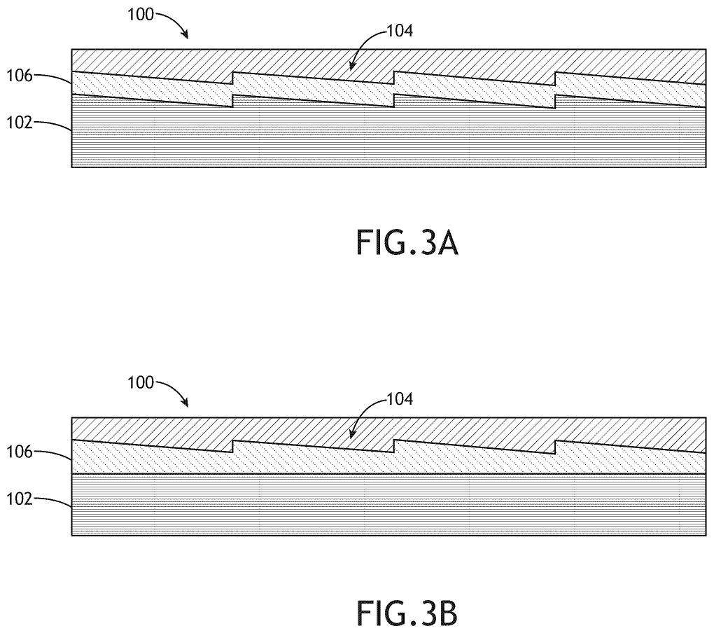

In embodiments, the blazed diffraction grating 106 can be formed by etching the grazing incidence mirror 102 (substrate) followed by coating as shown in FIG. 3A, or by etching the deposited coating 106 as shown in FIG. 3B. In some embodiments, depending on the substrate material, the substrate may be etched without coating. In embodiments, the grazing incidence mirror 102 may be flat or curved mirror. In embodiments, the blazed wavelength/SPF wavelength is not limited to EUV but can be extended to other wavelengths such as soft x-ray, DUV, and VUV regime. In embodiments, the blazed order is not limited to the +1st order, and any scattered order other than 0th order may work with enough coherence length. In embodiments, the +1st order may be preferred since the +1st order is solution matched to the problem and possible mixing with OOB, thereby providing a larger tolerance range to the design.

For the implementation of the reflective SPF 100 as shown in FIG. 2, the illuminated object may be a reticle, Si wafer, or any reflective/transmissive samples, and the imaging system 206 may be a projection system with the detector replaced with a Si wafer for lithography. In addition, the reflective SPF 100 may be implemented with or without the imaging system 206 but with a spatial filter such as a pinhole/slit configured to block all other OOB light to isolate the EUV light.

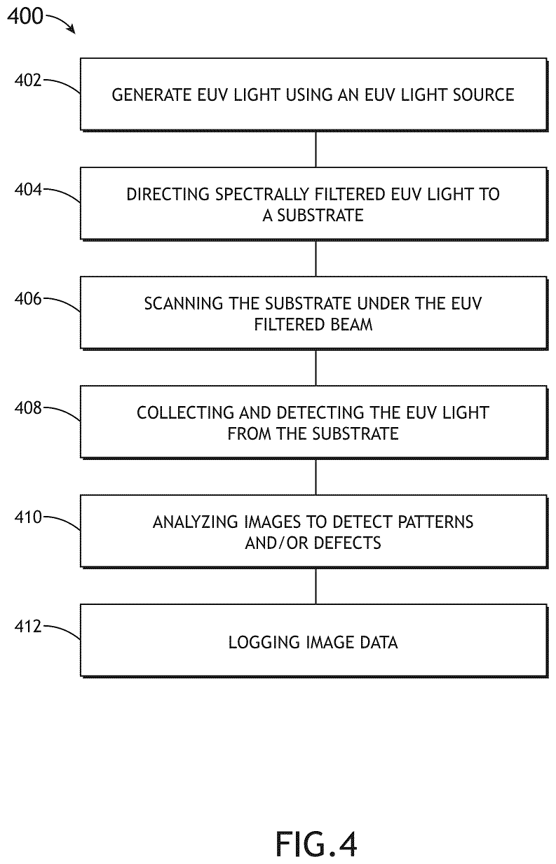

FIG. 4 illustrates a method 400 for substrate imaging (e.g., APMI) utilizing the reflective SPF 100 according to a present disclosure. In step 402, EUV light is generated by an EUV light source. In step 404, the EUV light, spectrally filtered by the reflective SPF 100, is directed to the substrate to be imaged. In step 406, the substrate is scanned under the spectrally filtered beam by the stage. In step 408, the diffracted and reflected EUV light is collected by an imaging system including imaging optics and projected to at least one detector. In step 410, a controller analyzes images collected by the one or more detectors to identify patterns and/or defects. In step 412, the method concludes with logging data pertaining the patterns and/or defects.

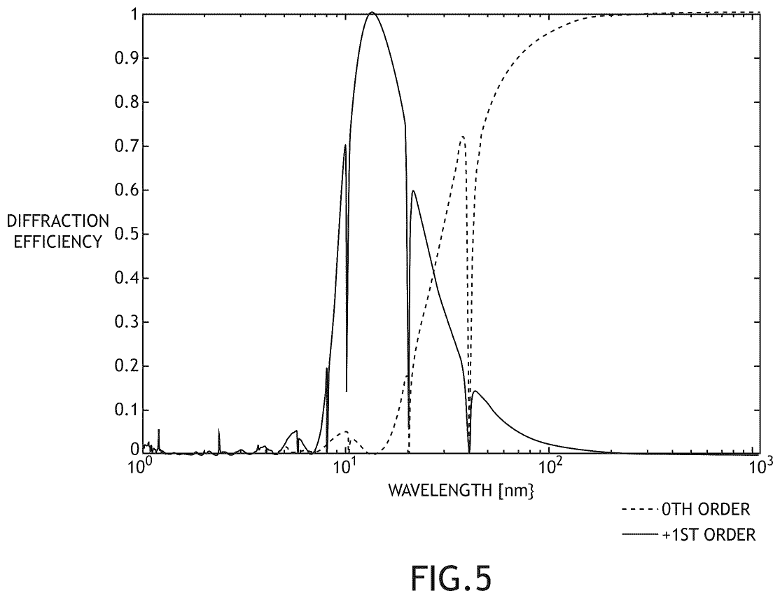

In a working example according to the present disclosure, a grazing incidence mirror having about a 70 degree illumination angle was configured with a blazed diffraction grating having a blaze angle θ_{B}=0.48° and a grating pitch T=2.3 μm to achieve an EUV grating transmission of up to 99.96% at the +1st order as illustrated in FIG. 5 or a grating pitch T=4.6 μm to achieve up to 99.99% at the +2nd order or even larger grating pitch to achieve higher order blazing. FIG. illustrates the grating diffraction efficiency of the 0th and +1st orders from 1 nm to 1100 nm, which demonstrates that the +1st order can select a narrow EUV band but also shows that nearly all the energy of longer wavelengths (e.g., >50 nm) is diffracted to the 0th order.

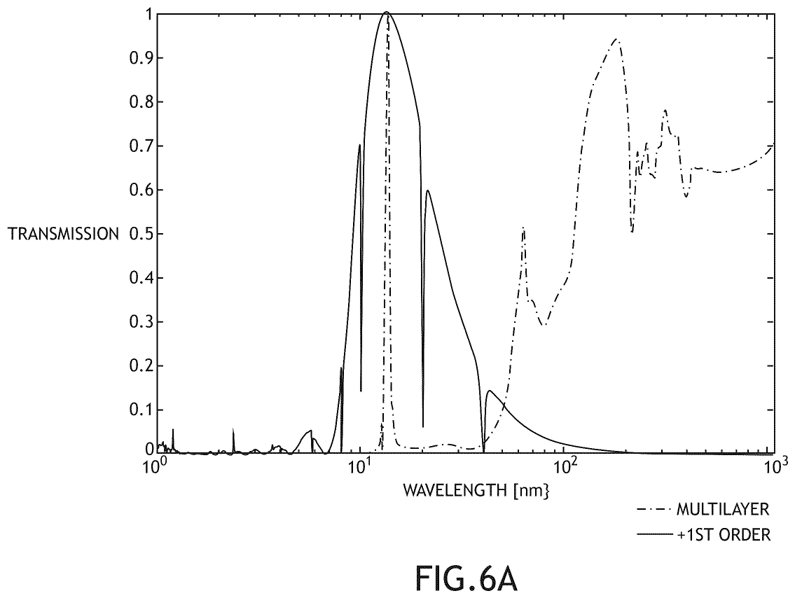

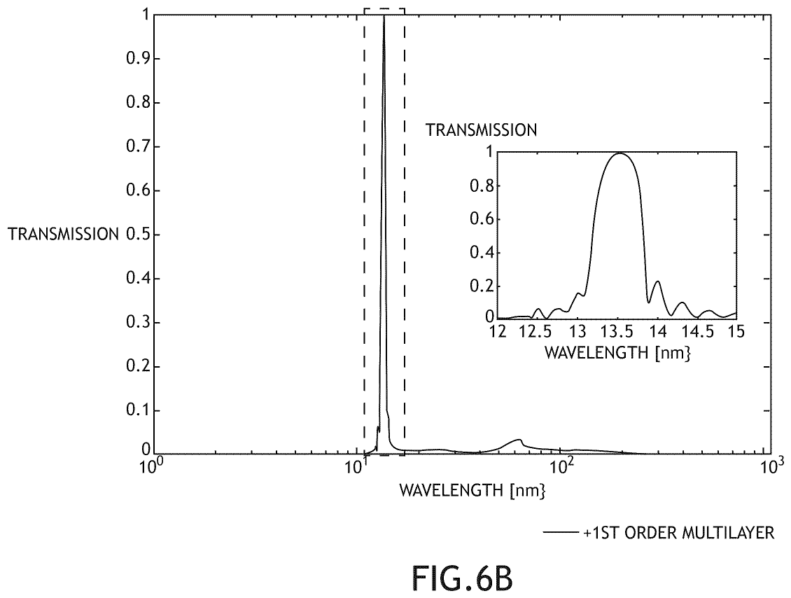

In addition, as implemented in an EUV optical system, either the upstream mirrors or the downstream imaging system will typically have normal incidence mirrors coated with Mo/Si multilayers. FIG. 6A illustrates a typical EUV multilayer relative transmission (dotted line) normalized by the peak reflectance given by 40 Mo/Si bilayers, where the OOB light will only have low reflectance at wavelength less than 40 nm. FIGS. 6a and 6b illustrate the reflective SPF spectral purity performance at the component level (FIG. 6a) and at the system level (FIG. 6B). The solid line in FIG. 6A depicts the +1st order of the blazed grating from FIG. 5. Their combination shown in FIG. 6b creates an almost perfect narrow EUV in-band (13-14 nm) transmission. As shown, the residual tail above 15 nm is nearly completely rejected by the imaging system due to angle separation. Also, with more multilayer mirror usage, the EUV band shown in the enlarge image in FIG. 6B would be narrower and the OOB even lower. As such, the image on the detector shown in FIG. 2 would be free of OOB light.

In embodiments, the spectral filter 100 according to the present disclosure having the blazed grating etched and/or coated on the grazing incidence mirror provide nearly 100% EUV transmission (excluding intrinsic coating reflectance) and rejects nearly 100% OOB light above 100 nm as a standalone performance. When combined with normal incidence EUV multilayer mirrors upstream/downstream in an imaging system, the combination can provide almost perfect narrow EUV band system level filtering of near 100% OOB beyond EUV in-band (13-14 nm).

In use, the blazed diffraction grating isolates and transfers the EUV beam energy away from the specular beam direction to isolate the EUV light from the OOB light in angle. A small blaze angle is sufficient to deflect the EUV wavelength from specular but insufficient to effect OOB light suppression in the specular beam, and a small pitch allows large OOB order separation creating order gaps that enable no light propagation at OOB wavelength but allowed light propagation modes in EUV at a certain diffraction angle.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components, and/or wirelessly interactable and/or wirelessly interacting components, and/or logically interacting and/or logically interactable components.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed:

1. A reflective spectral purity filter (SPF) for extreme ultraviolet (EUV) light comprising:
a substrate including a reflective surface having an angle of incidence of at least 60 degrees; and
a blazed diffraction grating formed on the substrate, the blazed diffraction grating having a predetermined grating pitch and blaze angle configured to simultaneously diffract incident EUV light into a higher-order diffraction angle and confine out-of-band (OOB) light to a 0th order reflection angle to angularly separate the EUV light and the OOB light.

2. The reflective SPF of claim 1, wherein the substrate is a grazing incidence mirror.

3. The reflective SPF of claim 2, wherein the grazing incidence mirror is flat or curved.

4. The reflective SPF of claim 1, wherein the higher-order diffraction angle corresponds to the +1st order.

5. The reflective SPF of claim 1, further comprising a reflective coating deposited on the substrate, wherein the blazed grating is etched on the reflective coating.

6. The reflective SPF of claim 1, wherein the predetermined grating pitch and blaze angle are fixed across the reflective surface of the substrate.

7. The reflective SPF of claim 1, wherein the predetermined grating pitch and blaze angle are variable across the reflective surface of the substrate.

8. The reflective SPF of claim 1, wherein the substrate is flat and the predetermined grating pitch and blaze angle are variable across the reflective surface to emulate optical properties of a curved substrate.

9. The reflective SPF of claim 1, wherein the grating pitch is between 0.025 μm and 100.0 μm and the blaze angle is between 0.01 degrees and 30.0 degrees.

10. The reflective SPF of claim 1, wherein the reflective SPF is configured to provide EUV transmission of at least 90%.

11. An imaging system comprising:
an extreme ultraviolet (EUV) light source configured to generate a beam of EUV light containing non-negligible out-of-band (OOB) light;
a reflective spectral purity filter (SPF) for EUV light comprising:
a substrate including a reflective surface having an angle of incidence of at least 60 degrees; and
a blazed diffraction grating formed on the substrate, the blazed diffraction grating having a predetermined grating pitch and blaze angle configured to simultaneously diffract incident EUV light into a higher-order diffraction angle and confine the non-negligible OOB light to a 0th order reflection angle to angularly separate the EUV light and the non-negligible OOB light;
a stage configured to hold a substrate to be inspected using the spatially filtered EUV light;
an imaging system including collection optics having a field of view (FOV) configured to collect the spatially filtered EUV light reflected from the substrate;
one or more detectors configured to detect the spatially filtered EUV light to inspect the substrate; and
a system controller including one or more processors.

12. The imaging system of claim 11, wherein the substrate is a grazing incidence mirror.

13. The imaging system of claim 12, wherein the grazing incidence mirror is flat or curved.

14. The imaging system of claim 11, wherein the higher-order diffraction angle corresponds to the +1st order.

15. The imaging system of claim 11, wherein the reflective SPF further comprises a reflective coating deposited on the substrate, wherein the blazed grating is etched on the reflective coating.

16. The imaging system of claim 11, wherein the predetermined grating pitch and blaze angle are fixed across the reflective surface of the substrate.

17. The imaging system claim 11, wherein the predetermined grating pitch and blaze angle are variable across the reflective surface of the substrate.

18. The imaging system of claim 11, wherein the substrate is flat and the predetermined grating pitch and blaze angle are variable across the reflective surface of the substrate to emulate optical properties of a curved substrate.

19. The imaging system of claim 11, wherein the grating pitch is between 0.025 μm and 100.0 μm and the blaze angle is between 0.01 degrees and 30.0 degrees.

20. The imaging system of claim 11, further comprising at least one normal incidence multilayer EUV mirror disposed upstream or downstream of the reflective SPF.

21. The imaging system of claim 20, wherein the reflective SPF is configured to provide EUV transmission of at least 90%, and the reflective SPF in combination with the at least one normal incidence multilayer EUV mirror are configured to provide EUV transmission of at least 99%.

22. A method for imaging a substrate, the method comprising:
generating, by an EUV light source, a beam of EUV light containing non-negligible out-of-band (OOB) light;
spatially filtering, by a reflective spectral purity filter (SPF) for EUV light comprising a substrate including a reflective surface having an angle of incidence of at least 60 degrees and a blazed diffraction grating formed on the substrate configured to simultaneously diffract incident EUV light into a higher-order diffraction angle and confine the non-negligible OOB light to a 0th order reflection angle to angularly separate the EUV light and the non-negligible OOB light, the EUV light;
directing, by the reflective SPF, the spatially filtered EUV light toward a substrate held on a stage;
collecting, by an imaging system having a field of view (FOV), the spatially filtered EUV light reflected from the substrate; and
detecting, by at least one detector, the collected spatially filtered EUV light.

23. The method of claim 22, wherein the substrate is a grazing incidence mirror.

24. The method of claim 23, wherein the grazing incidence mirror is flat or curved.

25. The method of claim 22, wherein a grating pitch and blaze angle of the blazed diffraction grating are fixed across the reflective surface of the substrate.

26. The method of claim 22, wherein a grating pitch and blaze angle of the blazed diffraction grating are variable across the reflective surface of the substrate.

27. The method of claim 22, wherein the substrate is flat and a grating pitch and blaze angle of the blazed diffraction grating are variable across the reflective surface of the substrate to emulate optical properties of a curved substrate.

28. The method of claim 22, wherein the higher-order diffraction angle corresponds to the +1st order.

29. The method of claim 22, wherein a grating pitch and blaze angle of the blazed diffraction grating are fixed or variable across the reflective surface of the substrate, and wherein the grating pitch is between 0.025 μm and 100.0 μm and the blaze angle is between 0.01 degrees and 30.0 degrees.

30. The method of claim 22, further comprising analyzing the collected spatially filtered EUV light to determine at least one a pattern and a defect.
